(19) United States
(12) Patent Application Publication
(10) Pub. No.: US 2025/0373213 A1
(43) Pub. Date: Dec. 4, 2025

(54) INTRA-SYMBOL VOLTAGE CHANGE ACCELERATION IN A WIRELESS TRANSMISSION CIRCUIT

(71) Applicant: Qorvo US, Inc., Greensboro, NC (US)

(72) Inventors: Nadim Khlat, Cugnaux (FR); Baker Scott, San Jose, CA (US); Woo Yong Lee, Chapel Hill, NC (US); George Maxim, Saratoga, CA (US)

(21) Appl. No.: 18/996,389

(22) PCT Filed: Aug. 28, 2023
(86) PCT No.: PCT/US2023/031228

§ 371 Date: Jan. 17, 2025

Related U.S. Application Data
(60) Provisional application No. 63/406,818, filed on Sep. 15, 2022.
(60) Provisional application No. 63/482,124, filed on Jan. 30, 2023.

(51) Int. Cl. H03F 3/195; H03F 1/32; H03F 3/24

(52) U.S. Cl. CPC H03F 3/195; H03F 1/3241; H03F 3/245; H03F 2200/102; H03F 2200/451

(57) ABSTRACT

Intra-symbol voltage change acceleration in a wireless transmission circuit is disclosed. The wireless transmission circuit includes a power amplifier circuit that amplifies a radio frequency (RF) signal based on an average power tracking (APT) voltage supplied by a power management integrated circuit (PMIC). The RF signal is modulated in multiple modulation symbols, such as orthogonal frequency division multiplex (OFDM) symbols. To prevent distortion (e.g., amplitude clipping) in the RF signal, the PMIC is configured to increase the APT voltage during each of the modulation symbols whenever the RF signal exceeds a predefined power threshold. Further, the PMIC is configured according to various acceleration embodiments to complete each APT volage change within a defined temporal limit (e.g., <1 μs). By supporting intra-symbol voltage change acceleration, the wireless transmission circuit can enable fast APT voltage adaptation to thereby improve operating efficiency of the power amplifier circuit.

### RELATED APPLICATIONS

This application claims the benefit of U.S. provisional patent application Ser. No. 63/406,818, filed on Sep. 15, 2022, and the benefit of U.S. provisional patent application Ser. No. 63/482,124, filed on Jan. 30, 2023, the disclosures of which are hereby incorporated herein by reference in their entireties.

### FIELD OF THE DISCLOSURE

The technology of the disclosure relates generally to intra-symbol voltage change acceleration in a wireless transmission circuit.

### BACKGROUND

Fifth generation (5G) new radio (NR) (5G-NR) has been widely regarded as the next generation of wireless communication technology beyond the current third generation (3G) and fourth generation (4G) technologies. In this regard, a wireless communication device capable of supporting the 5G-NR wireless communication technology is expected to achieve higher data rates, improved coverage range, enhanced signaling efficiency, and reduced latency.

Downlink and uplink transmissions in a 5G-NR system are widely based on orthogonal frequency division multiplexing (OFDM) technology. In an OFDM based system, physical radio resources are divided into a number of subcarriers in a frequency domain and a number of OFDM symbols in a time domain. The subcarriers are orthogonally separated from each other by a subcarrier spacing (SCS). The OFDM symbols are separated from each other by a cyclic prefix (CP), which acts as a guard band to help overcome inter-symbol interference (ISI) between the OFDM symbols.

A radio frequency (RF) signal communicated in the OFDM based system is often modulated into multiple subcarriers in the frequency domain and multiple OFDM symbols in the time domain. The multiple subcarriers occupied by the RF signal collectively define a modulation bandwidth of the RF signal. The multiple OFDM symbols, on the other hand, define multiple time intervals during which the RF signal is communicated. In the 5G-NR system, the RF signal is typically modulated with a high modulation bandwidth in excess of 200 MHz.

The duration of an OFDM symbol depends on the SCS and the modulation bandwidth. The table below (Table 1) provides some OFDM symbol durations, as defined by 3G partnership project (3GPP) standards for various SCSs and modulation bandwidths. Notably, the higher the modulation bandwidth is, the shorter the OFDM symbol duration will be. For example, when the SCS is 120 KHz and the modulation bandwidth is 400 MHZ, the OFDM symbol duration is 8.93 μs.

TABLE 1

| | | OFDM Symbol | Modulation |
|---|---|---|---|
| SCS | CP | Duration | Bandwidth |
| (KHz) | (μs) | (μs) | (MHz) |
| 15 | 4.69 | 71.43 | 50 |
| 30 | 2.34 | 35.71 | 100 |
| 60 | 1.17 | 17.86 | 200 |
| 120 | 0.59 | 8.93 | 400 |

In a 5G-NR system, the RF signal can be modulated with a time-variant power that changes from one OFDM symbol to another. In this regard, a power amplifier circuit(s) is required to amplify the RF signal to a certain power level within each OFDM symbol duration. Such inter-symbol power variation creates a unique challenge for a power management integrated circuit (PMIC). If the PMIC adapts a modulated voltage supplied to the power amplifier circuit based on an average power of the RF signal in an OFDM symbol duration, the modulated voltage may not be able to keep up with a peak power of the RF signal. As a result, the RF signal may be distorted due to, for example, amplitude clipping. On the other hand, if the PMIC adapts a modulated voltage supplied to the power amplifier circuit based on a peak power of the RF signal in an OFDM symbol duration, the modulated voltage may become excessive, thus causing energy waste to lower operating efficiency. Hence, it is desirable to prevent distortion to the RF signal while concurrently maintaining a reasonable level of operating efficiency.

### SUMMARY

Embodiments of the disclosure relate to intra-symbol voltage change acceleration in a wireless transmission circuit. The wireless transmission circuit includes a power amplifier circuit that amplifies a radio frequency (RF) signal based on an average power tracking (APT) voltage supplied by a power management integrated circuit (PMIC). The RF signal is modulated in multiple modulation symbols, such as orthogonal frequency division multiplex (OFDM) symbols. To prevent distortion (e.g., amplitude clipping) in the RF signal, the PMIC is configured to increase the APT voltage during each of the modulation symbols whenever the RF signal exceeds a predefined power threshold.

Further, the PMIC is configured according to various acceleration embodiments to complete each APT voltage change within a defined temporal limit (e.g., <1 μs). By supporting intra-symbol voltage change acceleration, the wireless transmission circuit can enable fast APT voltage adaptation to thereby improve operating efficiency of the power amplifier circuit.

In one aspect, a wireless transmission circuit is provided. The wireless transmission circuit includes a power amplifier circuit. The power amplifier circuit is configured to amplify an RF signal modulated in multiple modulation symbols based on an APT voltage. The wireless transmission circuit also includes a transceiver circuit. The transceiver circuit is configured to generate a target voltage in accordance with a time-variant power envelope of the RF signal. The wireless transmission circuit also includes a PMIC. The PMIC includes a voltage generation circuit. The voltage generation circuit is configured to generate the APT voltage in each of the plurality of modulation symbols based on the target voltage. The PMIC also includes a control circuit. The control circuit is configured to determine that the target voltage indicates one or more increased levels of the APT voltage relative to an average level of the APT voltage in a respective one of the multiple modulation symbols. The control circuit is also configured to control the voltage generation circuit to increase the APT voltage from the average level to each of the one or more increased levels within a defined temporal limit.

In another aspect, a method for accelerating intra-symbol voltage change is provided. The method includes amplifying an RF signal modulated in a plurality of modulation symbols based on an APT voltage. The method also includes generating a target voltage in accordance with a time-variant power envelope of the RF signal. The method also includes generating the APT voltage in each of the plurality of modulation symbols based on the target voltage. The method also includes determining that the target voltage indicates one or more increased levels of the APT voltage relative to an average level of the APT voltage in a respective one of the plurality of modulation symbols. The method also includes increasing the APT voltage from the average level to each of the one or more increased levels within a defined temporal limit.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an exemplary time slot(s) as widely supported in a fifth generation (5G) or a 5G new-radio (5G-NR) system for modulating a radio frequency (RF) signal;

FIG. 2 is a schematic diagram of an exemplary wireless transmission circuit wherein a power management integrated circuit (PMIC) and a transceiver circuit can be configured according to various embodiments of the present disclosure to support intra-symbol voltage change acceleration;

FIG. 3 is a graphic diagram providing an exemplary illustration as to how the transceiver circuit in FIG. 1 can generate a target voltage to enable the PMIC to provide intra-symbol voltage change acceleration;

FIG. 4 is a graphic diagram providing an exemplary illustration of a multi-damping scheme that can be employed by the PMIC in FIG. 2 to support intra-symbol voltage change acceleration;

FIG. 5 is a schematic diagram of the PMIC in FIG. 2 configured according to one embodiment of the present disclosure to support intra-symbol voltage change acceleration based on the multi-damping scheme of FIG. 4;

FIG. 6 is a graphic diagram providing an exemplary illustration of a multi-target scheme that can be employed by the PMIC in FIG. 5 to support intra-symbol voltage change acceleration;

FIG. 7 is a graphic diagram illustrating the multi-injection scheme performed by the PMIC in FIG. 2 to support intra-symbol voltage change acceleration;

FIG. 8 is a schematic diagram of the PMIC in FIG. 2, which is configured according to another embodiment of the present disclosure to accelerate intra-symbol voltage change based on the multi-injection scheme in FIG. 7;

FIG. 9 is a schematic diagram of the transceiver circuit in FIG. 2 that can be configured according to an embodiment to generate the modulated target voltage in FIG. 3;

FIG. 10 is a schematic diagram of an exemplary user element wherein the wireless transmission circuits of FIG. 2 can be provided; and

FIG. 11 is a flowchart of an exemplary process that may be employed by the wireless transmission circuit of FIG. 2 for accelerating intra-symbol voltage change.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to intra-symbol voltage change acceleration in a wireless transmission circuit. The wireless transmission circuit includes a power amplifier circuit that amplifies a radio frequency (RF) signal based on an average power tracking (APT) voltage supplied by a power management integrated circuit (PMIC). The RF signal is modulated in multiple modulation symbols, such as orthogonal frequency division multiplex (OFDM) symbols. To prevent distortion (e.g., amplitude clipping) in the RF signal, the PMIC is configured to increase the APT voltage during each of the modulation symbols whenever the RF signal exceeds a predefined power threshold.

Further, the PMIC is configured according to various acceleration embodiments to complete each APT volage change within a defined temporal limit (e.g., <1 μs). By supporting intra-symbol voltage change acceleration, the wireless transmission circuit can enable fast APT voltage adaptation to thereby improve operating efficiency of the power amplifier circuit.

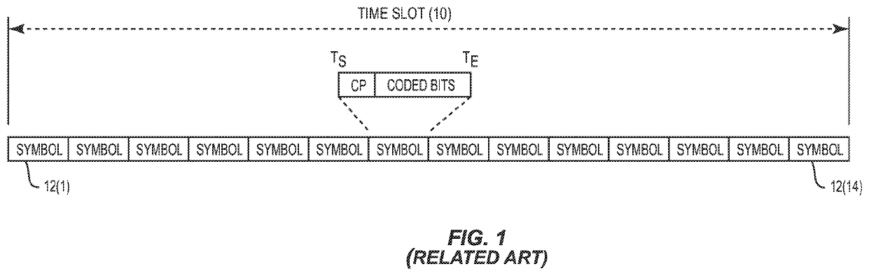

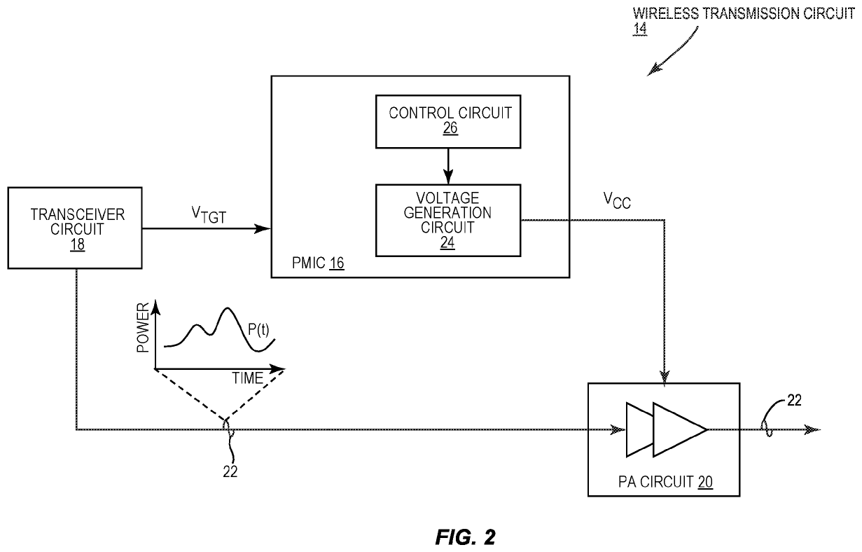

Before discussing intra-symbol voltage modulation according to the present disclosure, starting at FIG. 2, an overview of orthogonal frequency division multiplexing (OFDM) symbols, which can be used to define durations of voltage modulation intervals, is first provided with reference to FIG. 1.

FIG. 1 illustrates an exemplary time slot 10 as widely supported in a fifth generation (5G) and 5G new-generation (5G-NR) system for modulating an RF signal. The time slot(s) 10 is configured to include multiple OFDM symbols. In an exemplary configuration, the time slot 10 can include fourteen (14) OFDM symbols 12(1)-12(14).

As previously shown in Table 1, each of the symbols 12(1)-12(14) has a symbol duration that depends on the subcarrier spacing (SCS). In this regard, once the SCS is chosen, the duration and the CP of each of the symbols 12(1)-12 (14) are set accordingly. Hereinafter, each of the symbols 12(1)-12(14) is referred to generally as a modulation symbol.

Each of the symbols 12(1)-12(14) has a respective boundary, defined by a start time Ts and an end time T_{E}, and includes a cyclic prefix (CP) and a coded bit(s). Herein, the term “intra-symbol voltage change” refers generally to changing a voltage one or more times within the respective boundary of any of the symbols 12(1)-12(14).

FIG. 2 is a schematic diagram of an exemplary wireless transmission circuit 14 wherein a PMIC 16 and a transceiver circuit 18 can be configured according to various embodiments of the present disclosure to support intra-symbol voltage change acceleration within the respective boundary of any of the OFDM symbols 12(1)-12(14) in FIG. 1. For the convenience of illustration, a pair of consecutive modulation symbols S_{N-1}, S_{N} are used to represent any pair of consecutive symbols among the OFDM symbols 12(1)-12(14). Understandably, the modulation symbol S_{N-1} is an immediately preceding modulation symbol of the modulation symbol S_{N}. Accordingly, the modulation symbol S_{N} is an immediate succeeding modulation symbol of the modulation symbol S_{N-1}.

Herein, the wireless transmission circuit 14 includes a power amplifier circuit 20. The power amplifier circuit 20 is configured to amplify an RF signal 22 based on an APT voltage V_{CC}. The PMIC 16 is configured to generate the APT voltage V_{CC} based on a target voltage V_{TGT}. The transceiver circuit 18 is configured to generate the RF signal 22 associated with a time-variant power envelope P(t) and provide the RF signal 22 to the power amplifier circuit 20. The transceiver circuit 18 is also configured to generate the target voltage V_{TGT} in accordance with the time-variant power envelope P(t) and provide the target voltage V_{TGT} to the PMIC 16.

The PMIC 16 is configured to include a voltage generation circuit 24 and a control circuit 26. In an embodiment, the voltage generation circuit 24 may be a direct-current-to-direct-current (DC-DC) converter circuit, which can operate in a buck mode and/or a boost mode, to generate the APT voltage V_{CC}. The control circuit 26, on the other hand, can be configured according to various embodiments to accelerate intra-symbol changes of the APT voltage V_{CC}. As described in detail below, the control circuit 26 is configured to determine whether the target voltage V_{TGT} indicates an increased level(s) (denoted as “V_{CC+}” hereinafter) of the APT voltage V_{CC} relative to an average level (denoted as “V_{CC-AVG}” hereinafter) of the APT voltage V_{CC} in any modulation symbol, such as any of the OFDM symbols 12(1)-12(14) in FIG. 1. In response to determining that the target voltage V_{TGT} does indicate the increased level(s) of the APT voltage V_{CC}, the control circuit 26 will control the voltage generation circuit 24, based on a multi-damping scheme, a multi-target scheme, or a multi-injection scheme, to increase the APT voltage V_{CC} from the average level to the increased level(s) within a defined temporal limit (e.g., <1 microsecond). By supporting the intra-symbol voltage change acceleration, the wireless transmission circuit 14 can adapt the APT voltage V_{CC} in a timely manner to thereby improve operating efficiency of the power amplifier circuit 20 and prevent unwanted distortion (e.g., amplitude clipping) in the RF signal 22.

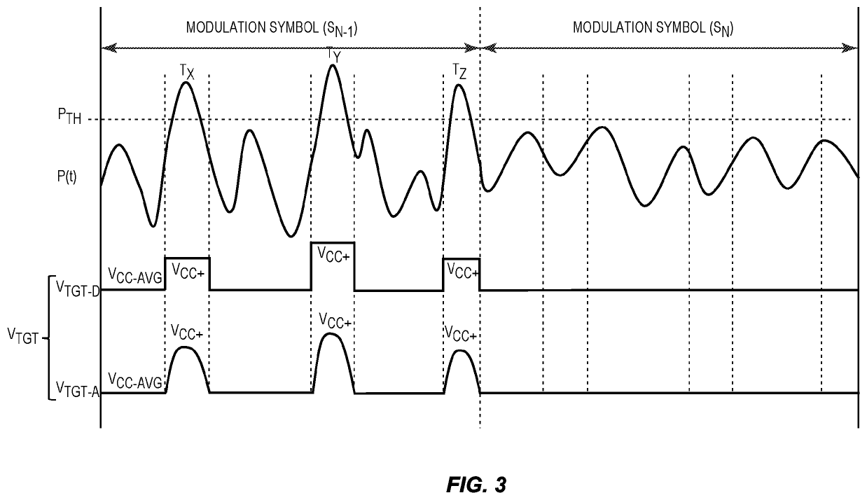

FIG. 3 is a graphic diagram providing an exemplary illustration as to how the transceiver circuit 18 in FIG. 1 can generate the target voltage V_{TGT} to enable the PMIC 16 to accelerate intra-symbol change of the APT voltage V_{CC}. In an embodiment, the transceiver circuit 18 is configured to generate the target voltage V_{TGT} by comparing the time-variant power envelope P(t) of the RF signal 22 against a predefined power threshold P_{TH}. Specifically, the transceiver circuit 18 will generate the target voltage V_{TGT} to indicate the increased level(s) of the APT voltage V_{CC} whenever the time-variant power envelope P(t) is higher than the predefined power threshold P_{TH} or to generate the target voltage V_{TGT} to indicate the average level of the APT voltage V_{CC} whenever the time-variant power envelope P(t) is lower than or equal to the predefined power threshold P_{TH}.

For example, during the modulation symbol S_{N-1}, the transceiver circuit 18 detects that the time-variant power envelope P(t) is higher than the predefined power threshold P_{TH} at times T_{X}, T_{Y}, and T_{Z}. Accordingly, the transceiver circuit 18 will generate the target voltage V_{TGT} to indicate the increased levels V_{CC+} of the APT voltage V_{CC} at times T_{X}, T_{Y}, and T_{Z}. In contrast, during the modulation symbol S_{N}, the time-variant power envelope P(t) is always lower than the predefined power threshold P_{TH}. As a result, the transceiver circuit 18 will generate the target voltage V_{TGT} to indicate the average level V_{CC-AVG} for an entire duration of the modulation symbol S_{N}. Herein, the transceiver circuit 18 may generate the target voltage V_{TGT} as a digital target voltage V_{TGT-D} and/or as an analog target voltage V_{TGT-A}.

To satisfy increasingly stringent switching budgets demanded by such advanced wireless communication systems as fifth generation (5G), 5G new-radio (5G-NR), and/or sixth generation (6G) systems, the PMIC 16 must be able to increase the APT voltage V_{CC} from the average level V_{CC-AVG} to each of the increased levels V_{CC+} within the defined temporal limit. In this regard, the wireless transmission circuit 14 of FIG. 2 can be configured to accelerate each change of the APT voltage V_{CC} within the defined temporal limit based on various embodiments described below.

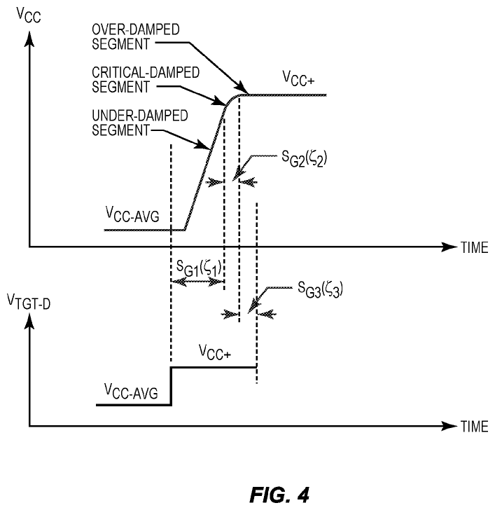

In one embodiment, the wireless transmission circuit 14 can be configured to accelerate an intra-symbol voltage change based on a multi-damping scheme. FIG. 4 is a graphic diagram providing an exemplary illustration of the multi-damping scheme that can be employed by the PMIC in FIG. 2 to support intra-symbol voltage change acceleration.

As an example, each change of the APT voltage V_{CC} from the average level V_{CC-AVG} to an increased level V_{CC+} during any of the modulation symbols S_{N-a 1}, S_{N} can be made based on a sequence of voltage change segments S_{G1}, S_{G2}, and S_{G3}. Each of the voltage change segments S_{G1}, S_{G2}, and S_{G3} is associated with a respective one of a sequence of voltage damping factors ζ₁, ζ₂, and ζ₃ (ζ₁≠ζ₂≠ζ₃).

Understandably, a voltage damping factor ζ is typically defined as a ratio between a load impedance (Z_{L}) and a source impedance (Z_{S}) (ζ=Z_{L}/Z_{S}) of a particular circuit. For a voltage converter, such as a DC-DC converter, the damping factor inversely determines a voltage settling time of the voltage converter. More specifically, the smaller the damping factor, the faster the voltage converter can change from one voltage level to another.

According to an embodiment of the present disclosure, the PMIC 16 is configured to increase the APT voltage V_{CC} at a fastest rate during the voltage change segment S_{G1} based on an over-damped voltage damping factor ζ₁ (ζ₁<1). During the voltage change segment S_{G2}, the PMIC 16 is configured to increase the APT voltage V_{CC} at a slower rate than that of the voltage change segment S_{G1} based on a critical-damped damping factor ζ₂ (ζ₂=1). Subsequently during the voltage change segment S_{G3}, the PMIC 16 is configured to increase the APT voltage V_{CC} at an even slower rate than that of the voltage change segment S_{G2} based on an under-damped damping factor ζ₃ (ζ₃>1).

In this regard, the voltage change segments S_{G1}, S_{G2}, and S_{G3} can be referred to as an over-damped segment, a critical-damped segment, and an under-damped segment, respectively. In a non-limiting example, the PMIC 16 is configured to increase the APT voltage V_{CC} to approximately 90% of the increased level V_{CC+} during the voltage change segment S_{G1} based on the over-damped voltage damping factor ζ₁ and to approximately 98% of the increased level V_{CC+} during the voltage change segment S_{G2} based on the critical-damped voltage damping factor ζ₂.

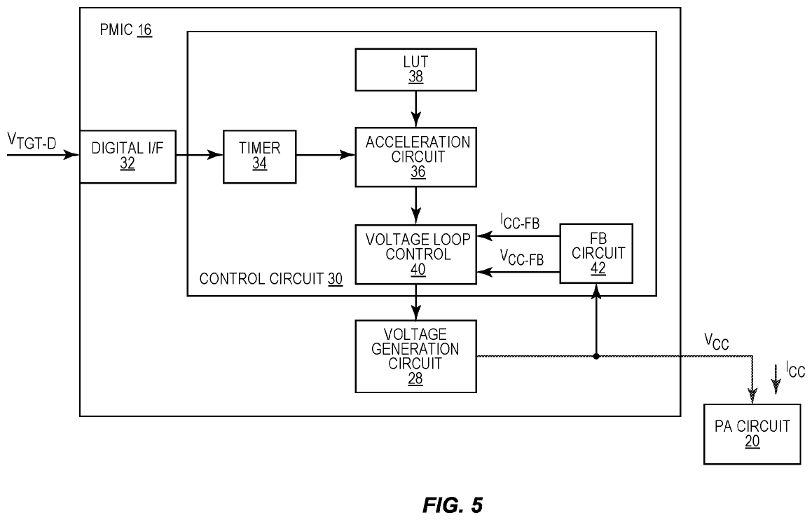

FIG. 5 is a schematic diagram of the PMIC 16 in FIG. 2 configured according to one embodiment of the present disclosure to support intra-symbol voltage change acceleration based on the multi-damping scheme of FIG. 4. Herein, the PMIC 16 includes a voltage generation circuit 28, a control circuit 30, and a digital interface 32. In a non-limiting example, the digital interface 32 can be an RF frontend (RFFE) interface. In an embodiment, the transceiver circuit 18 may be configured to provide the digital target voltage V_{TGT-D} during or prior to each of the modulation symbols S_{N-1}, S_{N} via multiple RFFE writes. The RFFE writes may be distributed uniformly or non-uniformly during a respective one of the symbols S_{N-1}, S_{N}.

In an embodiment, the voltage generation circuit 28 may be a DC-DC converter that can operate in a buck mode and/or a boost mode. The control circuit 30 is configured to receive the digital target voltage V_{TGT-D} from the transceiver circuit 18 via the digital interface 32 and control the voltage generation circuit 28 to generate the APT voltage V_{CC} in accordance with the digital target voltage V_{TGT-D}. Specifically, the control circuit 30 is configured to determine whether the target voltage V_{TGT-D} indicates a change of the APT voltage V_{CC} from the average level V_{CC-AVG} to the increased level V_{CC+} in any of the modulation symbols S_{N-1}, S_{N}. If so, the control circuit 30 will control the voltage generation circuit 28 based on the multi-damping scheme to change the APT voltage V_{CC} from the average level V_{CC-AVG} to each of the increased levels V_{CC+} within the defined temporal limit. Otherwise, the control circuit 30 will control the voltage generation circuit 28 to generate the APT voltage at the average level V_{CC-AVG}.

In a non-limiting example, the control circuit 30 can include a timer 34, an acceleration circuit 36, a lookup table (LUT) 38, a voltage loop control 40, and a feedback circuit 42. The LUT 38 may be used to store different loop coefficient values that are needed for the voltage loop control 40 for controlling the voltage generation circuit 28 based on the damping factors ζ₁, ζ₂, and ζ₃. The timer 34 may generate the sequence of voltage change segments S_{G1}, S_{G2}, S_{G3}. The acceleration circuit 36 may determine the damping factors ζ₁, ζ₂, and ζ₃ for the voltage change segments S_{G1}, S_{G2}, S_{G3} based on the loop coefficient values retrieved from the LUT 38 and provide the damping factors ζ₁, ζ₂, and ζ₃, and corresponding voltage change segments S_{G1}, S_{G2}, S_{G3}, to the voltage loop control 40. The voltage loop control 40, in turn, may control the voltage generation circuit 28 to change the APT voltage V_{CC} from the average level V_{CC-AVG} to the increased level V_{CC+} based on the determined damping factors ζ₁, ζ₂, and ζ₃. In an embodiment, the voltage loop control 40 may include a memory, a state machine engine, and/or an internal counter (not shown) to keep track of the position of the current settling process. The feedback circuit 42 may provide feedback of the APT voltage V_{CC} (denoted as V_{CC-FB}) and/or feedback of a load current I_{CC} (denoted as I_{CC-FB}) caused by the APT voltage V_{CC} to the voltage loop control 40.

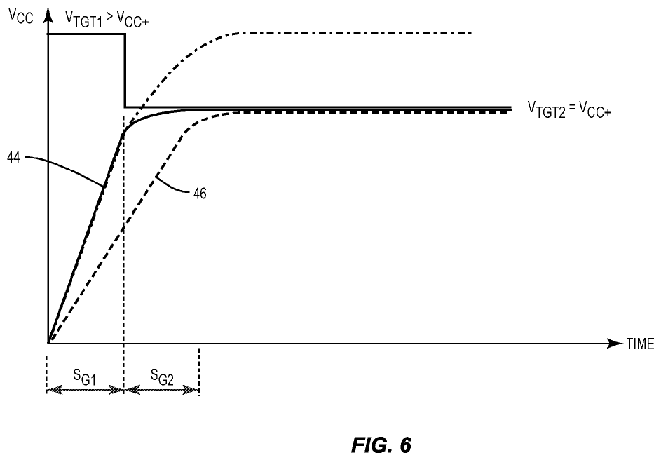

Alternative to supporting intra-symbol voltage change acceleration based on the multi-damping scheme, the PMIC 16 may be configured to support intra-symbol voltage change acceleration based on a multi-target scheme. In this regard, FIG. 6 is a graphic diagram providing an exemplary illustration of a multi-target scheme that can be employed by the PMIC 16 in FIG. 5 to support intra-symbol voltage change acceleration.

Herein, the acceleration circuit 36 may determine a sequence of voltage change segments S_{G1}, S_{G2} each associated with a respective one of multiple voltage targets V_{TGT1}, V_{TGT2}. More specifically, the acceleration circuit 36 may set an initial one of the voltage targets V_{TGT1}, V_{TGT2} (a.k.a. V_{TGT1}) in an initial one of the voltage change segments S_{G1}, S_{G2} (a.k.a. S_{G1}) to be higher than the increased level V_{CC+} in a respective one of the modulation symbols S_{N-1}, S_{N}. By setting the initial target voltage V_{TGT1} above the increased level V_{CC+}, the voltage generation circuit 28 can increase the APT voltage V_{CC} in the initial voltage change segment S_{G1} along a steeper curve 44. In contrast, if the initial target voltage V_{TGT1} is not set above the increased level V_{CC+}, the voltage generation circuit 28 can increase the APT voltage V_{CC} in the initial voltage change segment S_{G1} along a shallower curve 46. In addition, the acceleration circuit 36 may set a subsequent one of the voltage targets V_{TGT1}, V_{TGT2} (e.g., V_{TGT2}) in a subsequent one of the voltage change segments S_{G1}, S_{G2} (e.g., S_{G2}) to be equal to the increased level V_{CC+} in a respective one of the modulation symbols S_{N-1}, S_{N}.

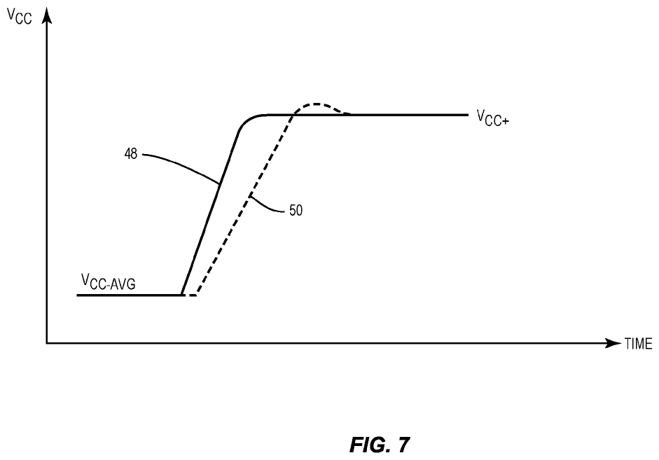

In another embodiment, the wireless transmission circuit 14 of FIG. 2 can be configured to accelerate intra-symbol voltage change based on a multi-injection scheme. In this regard, FIG. 7 is a graphic diagram illustrating a multi-injection scheme performed by the PMIC 16 in FIG. 2 to support intra-symbol voltage change acceleration.

As described in detail below, the PMIC 16 can be configured to inject one or more acceleration currents into one or more selected injection points to help accelerate a change of the APT voltage V_{CC} from the average level V_{CC-AVG} to the increased level V_{CC+} in a respective one of the modulation symbols S_{N-1}, S_{N}. As illustrated in FIG. 7, by injecting the acceleration currents into the selected injection points, the APT voltage V_{CC} will increase from the average level V_{CC-AVG} to the increased level V_{CC+} along a steeper curve 48. Without the acceleration currents, the APT voltage V_{CC} may have to increase from the average level V_{CC-AVG} to the increased level V_{CC+} along a shallower curve 50.

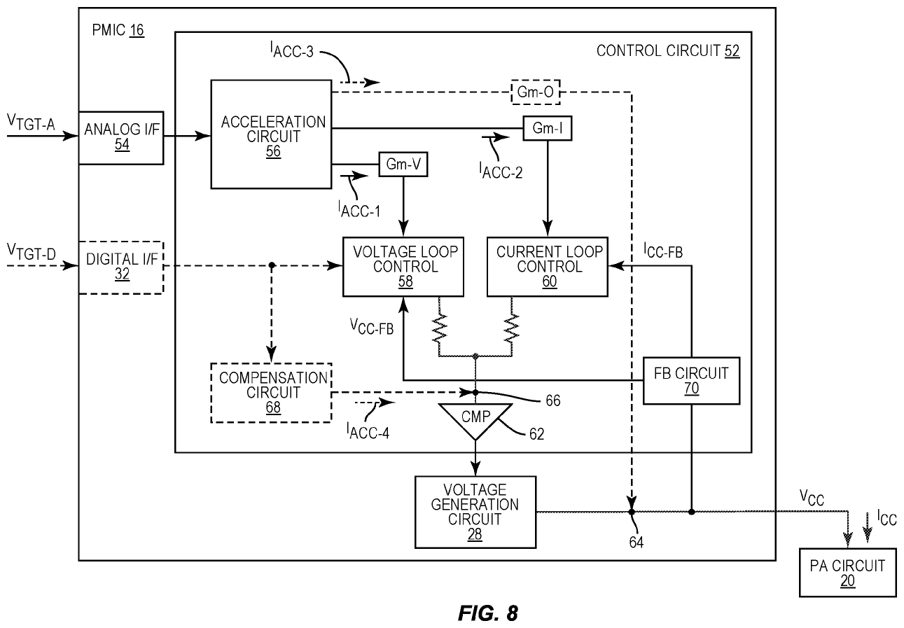

FIG. 8 is a schematic diagram of the PMIC 16 in FIG. 2, which is configured according to another embodiment of the present disclosure to accelerate intra-symbol voltage change based on the multi-injection scheme in FIG. 7. Common elements between FIGS. 5 and 8 are shown therein with common element numbers and will not be re-described herein.

Herein, the PMIC 16 includes a control circuit 52 and an analog interface 54. In an embodiment, the transceiver circuit 18 may be configured to provide the analog target voltage V_{TGT-A} during or prior to each of the modulation symbols S_{N-1}, S_{N} via the analog interface 54. The PMIC 16 may also include the digital interface 32, which may receive the digital target voltage V_{TGT-D} from the transceiver circuit 18, in addition to the analog target voltage V_{TGT-A}.

In an embodiment, the control circuit 52 includes an acceleration circuit 56, a voltage loop control 58, a current loop control 60, and a comparator 62. The acceleration circuit 56 is configured to generate one or more of multiple acceleration currents I_{ACC-1}, I_{ACC-2}, I_{ACC-3}, and I_{ACC-4} based on the analog target voltage V_{TGT-A}. Specifically, the acceleration circuit 56 may inject the acceleration current I_{ACC-1} into the voltage loop control 58 via a first transconductance circuit Gm-V and inject the acceleration current I_{ACC-2} into the current loop control 60 via a second transconductance circuit Gm-I. The acceleration circuit 56 may also inject the acceleration current I_{ACC-3} into an output 64 of the voltage generation circuit 28 via a third transconductance circuit Gm-O.

The acceleration circuit 56 may further inject the acceleration current I_{ACC-4} into an input 66 of the comparator 62 via a compensation circuit 68. The compensation circuit 68 may include variable components that may be needed when a pre-distortion of the target voltage is used. The PMIC 16 can also include a feedback circuit 70. The feedback circuit 70 can provide feedback of the APT voltage V_{CC} (denoted as V_{CC-FB}) and feedback of the load current I_{CC} (denoted as I_{CC-FB}) to the voltage loop control 58 and the current loop control 60, respectively.

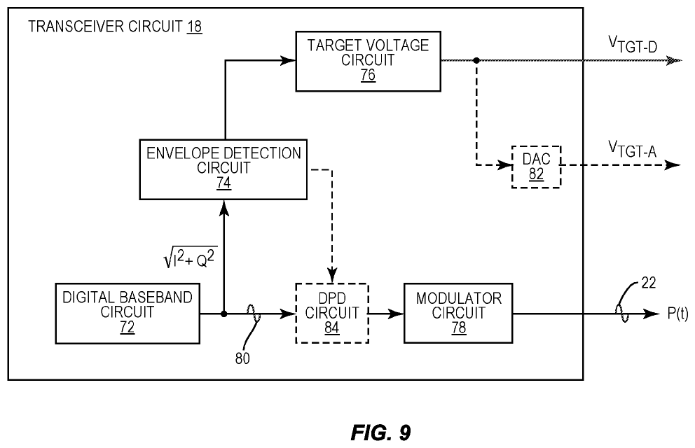

FIG. 9 is a schematic diagram of the transceiver circuit 18 in FIG. 2 that can be configured according to an embodiment to generate the modulated target voltage V_{TGT} in FIG. 3. Common elements between FIGS. 2 and 9 are shown therein with common element numbers and will not be re-described herein.

In an embodiment, the transceiver circuit 18 includes a digital baseband circuit 72, an envelope detection circuit 74, a target voltage circuit 76, and a modulator circuit 78. The digital baseband circuit 72 is configured to generate a digital signal 80, which can include an in-phase (I) component and a quadrature (Q) component. The I component and the Q component collectively define a time-variant amplitude envelope \sqrt{I²+Q²}. The envelope detection circuit 74 is configured to compare the time-variant amplitude envelope \sqrt{I²+Q²} against the predefined power threshold P_{TH} to determine whether to indicate the increased levels V_{CC+} of the APT voltage V_{CC} in the target voltage V_{TGT}. The target voltage circuit 76 is configured to generate the digital target voltage V_{TGT}-D to indicate the increased levels V_{CC+} in a respective one of the modulation symbols S_{N-1}, S_{N} whenever the envelope detection circuit 74 determines that the time-variant amplitude envelope \sqrt{I²+Q²} is above the predefined power threshold P_{TH}. The transceiver circuit 18 may include a digital-to-analog converter (DAC) 82, which may convert the digital target voltage V_{TGT-D} into the analog target voltage V_{TGT-A}.

The modulator circuit 78 is configured to convert the digital signal 80 into the RF signal 22. The modulator circuit 78 is also configured to generate the time-variant power envelope P(t) from the time-variant amplitude envelope \sqrt{R²+Q²}. The modulator circuit 78 may be further configured to upshift the RF signal 22 from a baseband frequency to an intermediate frequency (IF) or a carrier frequency.

The transceiver circuit 18 may further include a digital predistortion (DPD) circuit 84. The DPD circuit 84 can be configured to pre-distort the digital signal 80 to thereby correct potential amplitude-amplitude (AMAM) and/or amplitude-phase (AMPM) distortion in the RF signal 22 when the RF signal 22 is amplified at the power amplifier circuit 20. In an embodiment, the envelope detection circuit 74 may feed additional information into the DPD circuit 84 to help correct the AMAM and/or AMPM distortion.

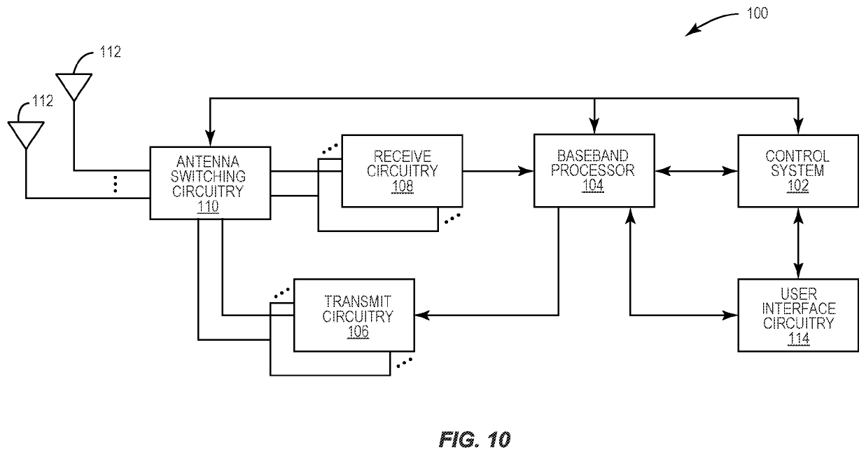

The wireless transmission circuit 14 of FIG. 2 can be provided in a user element to support intra-symbol voltage change acceleration according to embodiments described above. In this regard, FIG. 10 is a schematic diagram of an exemplary user element 100 wherein the wireless transmission circuit 14 of FIG. 1 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

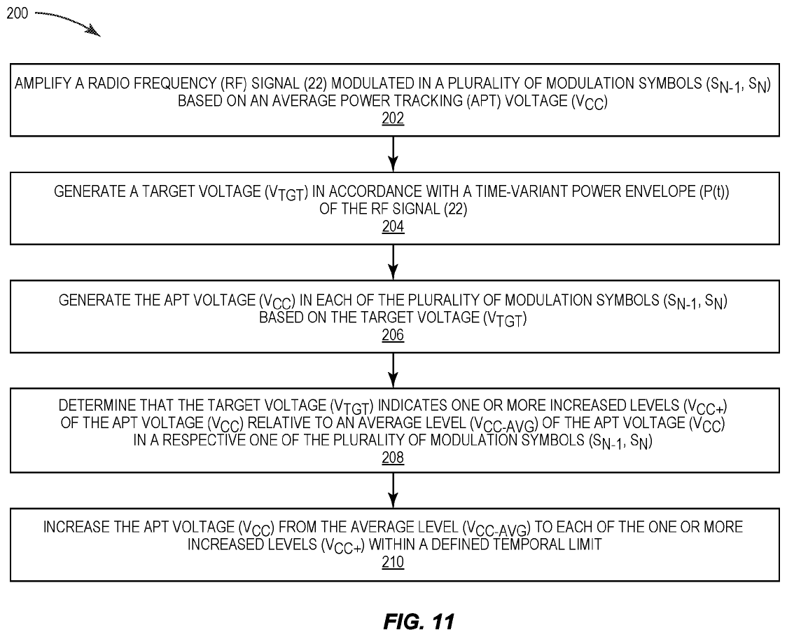

The wireless transmission circuit 14 of FIG. 2 can be configured to accelerate intra-symbol voltage change in accordance with a process. In this regard, FIG. 11 is a flowchart of an exemplary process 200 that can be employed by the wireless transmission circuit 14 of FIG. 2 for accelerating intra-symbol voltage change.

Herein, the power amplifier circuit 20 is configured to amplify the RF signal 22, which is modulated in the modulation symbols S_{N-1}, S_{N}, based on the APT voltage V_{CC} (step 202). The transceiver circuit 18 is configured to generate the target voltage V_{TGT} in accordance with the time-variant power envelope P(t) of the RF signal 22 (step 204). The voltage generation circuit 24 is configured to generate the APT voltage V_{CC} in each of the modulation symbols S_{N-1}, S_{N} based on the target voltage V_{TGT} (step 206). The control circuit 26 is configured to determine that the target voltage V_{TGT} indicates the increased levels V_{CC+} of the APT voltage V_{CC} relative to the average level V_{CC-AVG} of the APT voltage V_{CC} in a respective one of the modulation symbols S_{N-1}, S_{N} (step 208). Accordingly, the voltage generation circuit 24 increases the APT voltage V_{CC} from the average level V_{CC-AVG} to each of the increased levels V_{CC+} within the defined temporal limit (step 210).

Those skilled in the art will recognize improvements and modifications to the preferred embodiments of the present disclosure. All such improvements and modifications are considered within the scope of the concepts disclosed herein and the claims that follow.

1. A wireless transmission circuit comprising:
a power amplifier circuit configured to amplify a radio frequency (RF) signal modulated in a plurality of modulation symbols based on an average power tracking (APT) voltage;
a transceiver circuit configured to generate a target voltage in accordance with a time-variant power envelope of the RF signal; and
a power management integrated circuit (PMIC) comprising:
a voltage generation circuit configured to generate the APT voltage in each of the plurality of modulation symbols based on the target voltage; and
a control circuit configured to:
determine that the target voltage indicates one or more increased levels of the APT voltage relative to an average level of the APT voltage in a respective one of the plurality of modulation symbols; and
control the voltage generation circuit to increase the APT voltage from the average level to each of the one or more increased levels within a defined temporal limit.

2. The wireless transmission circuit of claim 1, wherein the transceiver circuit is further configured to:
compare the time-variant power envelope of the RF signal against a predefined power threshold;
indicate the one or more increased levels of the APT voltage in the target voltage whenever the time-variant power envelope is higher than the predefined power threshold; and
indicate the average level of the APT voltage in the target voltage whenever the time-variant power envelope is lower than or equal to the predefined power threshold.

3. The wireless transmission circuit of claim 2,
wherein the transceiver circuit comprises:
a digital baseband circuit configured to generate a digital signal associated with a time-variant amplitude envelope;
a modulator circuit configured to convert the digital signal into the RF signal associated with the time-variant power envelope;
an envelope detection circuit configured to compare the time-variant amplitude envelope against the predefined power threshold;
a target voltage circuit configured to generate a digital target voltage to:
indicate the one or more increased levels of the APT voltage whenever the time-variant power envelope is higher than the predefined power threshold; and
indicate the average level of the APT voltage whenever the time-variant power envelope is lower than or equal to the predefined power threshold; and
a digital-to-analog converter, DAC, configured to convert the digital target voltage into an analog target voltage.

4. The wireless transmission circuit of claim 3,
wherein the transceiver circuit further comprises a digital predistortion (DPD) circuit coupled between the digital baseband circuit and the modulator circuit, the DPD circuit is configured to pre-distort the digital signal to thereby correct one or more of an amplitude-amplitude (AMAM) distortion and an amplitude-phase, AMPM, distortion in the RF signal.

5. The wireless transmission circuit of claim 3,
wherein the transceiver circuit is further configured to generate the target voltage comprising the digital target voltage.

6. The wireless transmission circuit of claim 5,
wherein, for each of the one or more increased levels of the APT voltage, the control circuit is further configured to:
determine a sequence of voltage change segments each associated with a respective one of a sequence of voltage damping factors organized in an ascending order; and
control the voltage generation circuit to increase the APT voltage from the average level to a respective one of the one or more increased levels in accordance with the sequence of voltage damping factors.

7. The wireless transmission circuit of claim 6,
wherein the sequence of voltage change segments comprises:
an over-damped segment associated with a smallest one of the sequence of voltage damping factors;
a critical-damped segment with an intermediate one of the sequence of voltage damping factors; and
an under-damped segment with a highest one of the sequence of voltage damping factors.

8. The wireless transmission circuit of claim 6,
wherein the control circuit comprises:
a timer configured to generate the sequence of voltage change segments;
a lookup table (LUT), configured to store multiple loop coefficient values;
an acceleration circuit configured to determine the sequence of voltage damping factors based on the multiple loop coefficient values stored in the LUT; and
a voltage loop control configured to control the voltage generation circuit to increase the APT voltage from the average level to the respective one of the one or more increased levels in accordance with the sequence of voltage damping factors.

9. The wireless transmission circuit of claim 5,
wherein, for each of the one or more increased levels of the APT voltage, the control circuit is further configured to:
determine a sequence of voltage change segments each associated with a respective one of multiple voltage targets indicating a respective one of the one or more increased levels of the APT voltage, wherein an initial one of the multiple voltage targets is higher than the respective one of the one or more increased levels of the APT voltage in a respective one of the sequence of voltage change segments; and
control the voltage generation circuit to increase the APT voltage from the average level to the respective one of the one or more increased levels in accordance with the multiple voltage targets.

10. The wireless transmission circuit of claim 3,
wherein the transceiver circuit is further configured to generate the target voltage comprising the analog target voltage.

11. The wireless transmission circuit of claim 10,
wherein, for each of the one or more increased levels of the APT voltage, the control circuit is further configured to:
generate one or more acceleration currents from the analog target voltage; and
inject the one or more acceleration currents into one or more selected injection points to thereby cause the voltage generation circuit to increase the APT voltage from the average level to a respective one of the one or more increased levels within the defined temporal limit.

12. The wireless transmission circuit of claim 11,
wherein the control circuit comprises an acceleration circuit configured to generate the one or more acceleration currents based on the analog target voltage and inject the one or more acceleration currents into the one or more selected injection points.

13. The wireless transmission circuit of claim 12, wherein the one or more selected injection points comprise one or more of a voltage loop control, a current loop control, and an output of the voltage generation circuit.

14. A method for accelerating intra-symbol voltage change comprising:
amplifying a radio frequency (RF) signal modulated in a plurality of modulation symbols based on an average power tracking (APT) voltage;
generating a target voltage in accordance with a time-variant power envelope of the RF signal;
generating the APT voltage in each of the plurality of modulation symbols based on the target voltage;
determining that the target voltage indicates one or more increased levels of the APT voltage relative to an average level of the APT voltage in a respective one of the plurality of modulation symbols; and
increasing the APT voltage from the average level to each of the one or more increased levels within a defined temporal limit.

15. The method of claim 14, further comprising:
comparing the time-variant power envelope of the RF signal against a predefined power threshold;
indicating the one or more increased levels of the APT voltage in the target voltage whenever the time-variant power envelope is higher than the predefined power threshold; and
indicating the average level of the APT voltage in the target voltage whenever the time-variant power envelope is lower than or equal to the predefined power threshold.

16. The method of claim 14, wherein generating the target voltage comprises generating a digital target voltage.

17. The method of claim 16, further comprising, for each of the one or more increased levels of the APT voltage:
determining a sequence of voltage change segments each associated with a respective one of a sequence of voltage damping factors organized in an ascending order; and
increasing the APT voltage from the average level to a respective one of the one or more increased levels in accordance with the sequence of voltage damping factors.

18. The method of claim 16, further comprising, for each of the one or more increased levels of the APT voltage:
determining a sequence of voltage change segments each associated with a respective one of multiple voltage targets indicating a respective one of the one or more increased levels of the APT voltage, wherein an initial one of the multiple voltage targets is higher than the respective one of the one or more increased levels of the APT voltage in a respective one of the sequence of voltage change segments; and
increasing the APT voltage from the average level to the respective one of the one or more increased levels in accordance with the multiple voltage targets.

19. The method of claim 14, wherein generating the target voltage comprises generating an analog target voltage.

20. The method of claim 19, further comprising, for each of the one or more increased levels of the APT voltage:
generating one or more acceleration currents from the analog target voltage; and
injecting the one or more acceleration currents into one or more selected injection points to thereby increase the APT voltage from the average level to a respective one of the one or more increased levels within the defined temporal limit.
